(19) United States
(12) Patent Application Publication
(10) Pub. No.: US 2026/0078046 A1
(43) Pub. Date: Mar. 19, 2026

(54) PLASMA-BASED GLASS PACKAGE DICING

(71) Applicant: Intel Corporation, Santa Clara, CA (US)

(72) Inventors: Wei WEI, Chandler, AZ (US); Xiyu HU, Phoenix, AZ (US); Xiao LIU, Chandler, AZ (US); Haobo CHEN, Chandler, AZ (US); Bohan SHAN, Tempe, AZ (US); Xiaoying GUO, Chandler, AZ (US); Gang DUAN, Chandler, AZ (US); Srinivas PIETAMBARAM, Chandler, AZ (US); Hiroki TANAKA, Gilbert, AZ (US); Hongxia FENG, Chandler, AZ (US); Praveen SREERAMAGIRI, Gilbert, AZ (US); Christy PRATHER, Gilbert, AZ (US); Jesse JONES, Chandler, AZ (US); Leonel ARANA, Phoenix, AZ (US); Rahul MANEPALLI, Chandler, AZ (US)

(21) Appl. No.: 18/888,213

(22) Filed: Sep. 18, 2024

(51) Int. Cl. C03B 33/07; H01L 21/48; H01L 23/498

(52) U.S. Cl. CPC C03B 33/07; H10W 70/048; H10W 70/685

(57) ABSTRACT

According to the various aspects, a method is provided for dicing a semiconductor panel having a glass core with topside build-up (BU) layers, backside BU layers, and interconnects. In an aspect, a hard mask is deposited on the semiconductor panel and patterned to form openings for a plurality of cut-streets. In an aspect, the dicing of the semiconductor panel includes using plasma dicing steps to form cut-streets through the topside BU layers and the backside BU layers, and using a mechanical sawing step or plasma dicing step to cut through the glass core. In another aspect, the dicing of the semiconductor panel further includes using an acid rinse to remove metal salts when cutting through the glass core during the plasma dicing step. In another aspect, a singulated die may have a first BU sidewall and a second BU sidewall having a morphology that includes semi-sphere fillers.

### BACKGROUND

As semiconductor technology advances, the need to improve performance and lower costs for integrated circuit design and fabrication are constant challenges. It is becoming more difficult and costly to realize high-volume manufacturing for semiconductors as transistors continue to shrink in size. Cost savings may be potentially realized by building more efficient structures and using materials that improve power performance and yields.

Presently, glass is a commonly used substrate or core for manufacturing semiconductors. It is a low-cost material with excellent properties, such as high thermal resistance, chemical resistance, high flatness, low coefficient of thermal expansion, etc. In addition, glass substrates have high smoothness and shape stability that may contribute to the prevention of yield degradation due to defects arising from various processing steps. However, glass is an amorphous material and cannot be easily etched anisotropically and/or separated into dies.

In a back-end package process, dicing is performed to divide wafers and panels into individual chips. Such individualization of a wafer or panel into multiple chips is called “singulation”, and a process of sawing a wafer plate into a single cuboid is called “die sawing”. For the dicing and singulation of glass substrates, the use of mechanical sawing (e.g., cutting glass substrate with hard metal/diamond spinning blades), and laser cutting (e.g., using a laser beam to heat a localized area of the glass that can be cooled rapidly to induce thermal stress and create a controlled crack), have traditionally been the predominant technologies. These methods may encounter significant challenges when applied in isolation under stringent cutting conditions, especially as the height of the substrate layer stack increases with build-up (BU) layers, interconnects, devices, and other features formed on the glass substrate.

For such conditions, the stress induced by cutting may lead to glass delamination, breakage, and other compatibility challenges. The use of dicing and singulation processes that allow glass substrates/cores and the build-up layers thereon to be easily separated and that result in reduced mechanical stress and thermally-induced stress may provide lower costs and improve yields.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1A through 1G show exemplary representations of a method of dicing a semiconductor panel according to an aspect of the present disclosure;

FIG. 2 shows a simplified flow diagram for an exemplary method according to an aspect of the present disclosure;

FIGS. 3A through 3G show exemplary representations of another method of dicing a semiconductor panel according to an aspect of the present disclosure;

FIGS. 4A and 4B show a simplified flow diagram for another exemplary method according to an aspect of the present disclosure; and

FIG. 5 shows an exemplary image of a sidewall of build-up layers according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, a present use of plasma cutting provides enhanced glass dicing processes that may improve yields and quality control. In an aspect, the present methods may use plasma cutting operations, at a low temperature (<100 C.), which includes two ways of using the present plasma cutting to: 1) directly remove the build-up (BU) layers (i.e., topside and backside layers) and the glass core in the “cut-streets” (a.k.a. dicing streets or scribes) of a semiconductor panel or wafer; and 2) assist in the dicing of the semiconductor panel or wafer by removing only the BU layers in the cut-streets. The plasma cutting prevents heat-induced stress and cracking in the glass core. In addition, the present dies may have BU layers with edge sidewalls with a morphology of semi-sphere fillers, as compared with a full filler structure that results from laser cutting or mechanical sawing.

The present disclosure provides a method for dicing a semiconductor panel having a glass core with topside build-up (BU) layers, backside BU layers, and interconnects. In an aspect of the method, a hard mask is deposited on the semiconductor panel and patterned to form a plurality of openings for cut-streets to be used for dicing/singulation. In an aspect, the dicing of the semiconductor panel includes using plasma dicing steps to form cut-streets through the topside BU layers and the backside BU layers and using a plasma dicing step to cut through the glass core. The plasma dicing step may be performed using reactive ion etching, which provides an etch in a downward direction with controlled sideways etching. In another aspect, the dicing of the semiconductor panel further includes using an acid rinse to remove metal salts, which may be formed when dopants are used in the glass core, when cutting through the glass core during the plasma dicing step.

The present disclosure is also directed to a method for dicing a semiconductor panel that includes a glass core with topside and backside surfaces, topside BU layers and backside BU layers, and interconnects. In an aspect of the method, a first hard mask may be deposited on the semiconductor panel over the topside BU layers and patterned to form a first opening for a plurality of first cut-streets. In an aspect, a first plasma dicing step is performed to cut through the topside BU layers. Thereafter, the first hard mask is removed and the semiconductor panel is turned over and a second hard mask is deposited on the semiconductor panel over the backside BU layers and patterned to form a second opening for a plurality of second cut-streets. In an aspect, a second plasma dicing step is used to cut through the backside BU layers. In another aspect, a mechanical sawing step may be used to cut through the glass core to dice the semiconductor panel. It is within the scope of the present disclosure to substitute the mechanical sawing step with a third plasma dicing step.

The present disclosure is further directed to a semiconductor die including a glass core having a first surface, a glass sidewall, and a second surface. In an aspect, a first BU layer having a first BU sidewall is disposed on the first surface of the glass core and a second BU layer having a second BU sidewall is disposed on the second surface of the glass core. the first and second BU sidewalls are vertically aligned with the glass sidewall. In an aspect, the first BU sidewall and second BU sidewall have a morphology that includes semi-sphere fillers.

The technical advantages of the present disclosure include, but are not limited to:
(i) providing the use of plasma-assisted cutting to remove the build-up layers from cut-streets at a lower temperature than laser cutting, which prevents heat-induced stress generation that cracks in a glass semiconductor panel;
(ii) providing the use of plasma cutting to remove the build-up layers and a glass core from cut-streets at a lower temperature than laser cutting, which prevents heat-induced stress generation that cracks in a glass semiconductor panel; and
(iii) providing the use of plasma cutting as a lower-cost substitute for laser cutting and mechanical sawing when dicing a glass semiconductor panel, which provides better yields and quality control.

To more readily understand and put into practical effect the present methods and devices resulting therefrom, which may provide improved manufacturing yields and performance, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

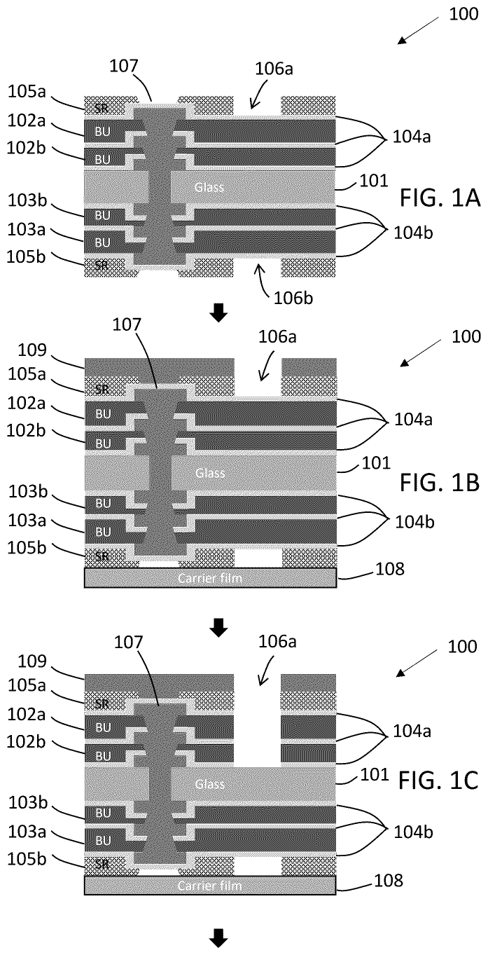

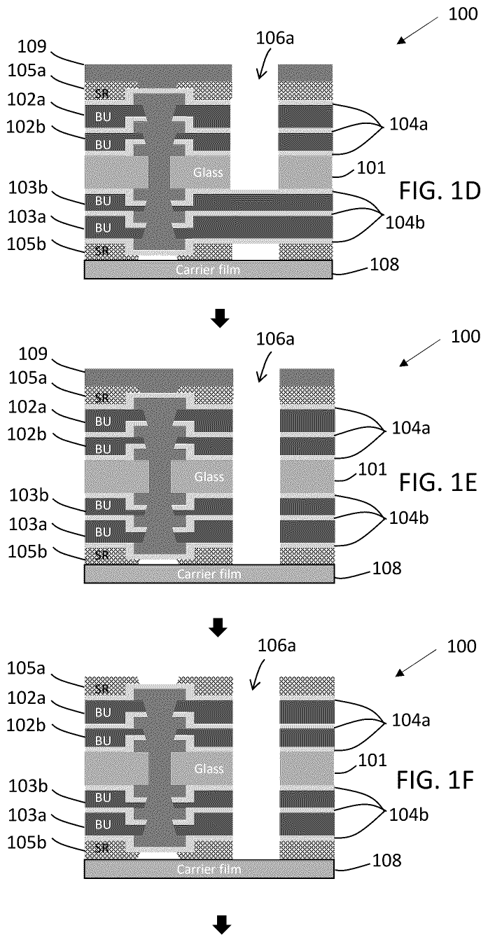

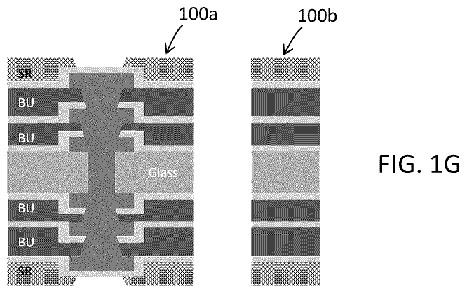

FIGS. 1A through 1G show exemplary representations of a method for the dicing of a semiconductor panel 100 according to an aspect of the present disclosure.

In FIG. 1A, the semiconductor panel 100 includes a glass core 101 having topside build-up layers 102a and 102b and backside build-up layers 103a and 103b, which include a plurality of wiring layers made of metal lines, a.k.a., build-up wiring, that are typically separated by a compound material of glass filler and resin. A topside solder resist layer 105a may be disposed over the topside build-up layers 102a and a backside solder resist layer 105b may be disposed over the backside build-up layers 103a. It should be understood that the number of build-up layers that may be used will vary depending on a semiconductor layout design.

In an aspect, a build-up layer may have a thickness of greater than 100 μm and may typically have a thickness in the range of approximately 50 to 150 μm. In another aspect, a glass core may typically have a thickness in the range of approximately 200 to 1100 μm.

In an aspect, a plurality of topside insulating layers 104a may be disposed between the topside solder resist layer 105a, the topside build-up layers 102a, the topside build-up layers 102b and the glass core 101, and similarly, a plurality of backside insulating layers 104b may be disposed between the backside solder resist layer 105b, the backside build-up layers 103a, the backside build-up layers 103b and the glass core 101.

In an aspect, the topside solder resist layer 105a may have a topside opening 106a and the backside solder resist layer 105b may have a backside opening 106b, which are positioned at a location for a cut-street to be used for dicing/singulation of the semiconductor panel 100. It should be understood that the semiconductor panel 100 may have a plurality of cut-streets that will need to be formed for dicing/singulation.

In another aspect, as shown in FIG. 1A, an interconnect 107 may be formed in the semiconductor panel 100 to connect the topside build-up layers 102a and 102b with the backside build-up layers 103a and 103b, as well as providing connections with other semiconductor components (not shown). It should be understood that the interconnect 107 is representative of the various through-glass vias (TGVs), microvias and other interconnects that may be used for a semiconductor layout design.

In FIG. 1B, the semiconductor panel 100 may be provided with a carrier film 108, e.g., a polyester film, that is laminated onto the backside of the semiconductor panel 100 and provides integrity for the semiconductor panel 100 by holding the singulated dies together after completion of the process. In an aspect, a hard mask layer 109, e.g., a Cu mask layer, may be deposited on the topside solder resist 105a and patterned by a conventional lithography method to maintain the opening 106a. The hard mask layer 109 may be provided as a protective layer that enables the cut-streets to be selectively formed in the semiconductor panel 100 during the dicing/singulation process.

In FIG. 1C, the depth of the topside opening 106a may be further increased by a first plasma dicing step to remove the topside build-up layers 102a and 102b, as well as removing the topside insulating layers 104a to expose the glass core 101 as part of the dicing process. The first plasma dicing step may be performed using a conventional plasma etch technology; for example, a reactive ion etching method using a carbon tetrafluoride/oxygen plasma. It is important to note that precise termination at the interface with the glass core 101 is not critical, rather the primary concern is to minimize excessive over-etching. In an aspect, the singulation process may provide heat management by way of an electrostatic chuck (ESC) (not shown), which may be provided to support the semiconductor panel 100.

In FIG. 1D, the depth of the topside opening 106a may be further increased by a second plasma dicing step to remove the glass core 101. The second plasma dicing step may be performed using a conventional plasma etch technology; for example, a reactive ion etching method using a nitrogen trifluoride (NF₃)/oxygen plasma. In an aspect, depending on the glass type used, an acid rinse cycle may be needed to remove impurities, e.g., salt byproducts.

When cutting through a glass material, it is important to consider its composition and whether or not it includes a high concentration of metal ions. The metal ions may create an etching barrier and increase surface roughness during a plasma etching process. To achieve a deep etch into the glass material, which may be potentially hundreds of microns thick, an acid rinse may be necessary to remove the salts formed during etching. For example, when using NF₃ gas, calcium and aluminum ions can form CaF2 and AlF₃ salts, respectively. These salts are not volatile and tend to accumulate at the bottom of the etched saw-street. However, they are readily soluble in acidic aqueous solutions, e.g., sulfuric acids, which allows for their effective removal via a cyclical rinsing process.

In FIG. 1E, the depth of the topside opening 106a may be further increased by a third plasma dicing step to remove the backside build-up layers 103b and 103a and the backside insulating layers 104b as part of the dicing process. The third plasma dicing step may be performed using a conventional plasma etch technology; for example, a reactive ion etching method using a carbon tetrafluoride/oxygen plasma.

In FIG. 1F, the hard mask layer 109, e.g., a Cu mask layer, may be removed from the topside solder resist 105a using a conventional layer stripping method, e.g., a Cu etching method.

In FIG. 1G, the dicing/singulation of the semiconductor panel 100 may be completed by the formation of dies 100a and 100b and the removal of the carrier film 108 by, for example, an ultraviolet (UV) debonding step. The singulated dies 100a and 100b may be further processed by conventional procedures.

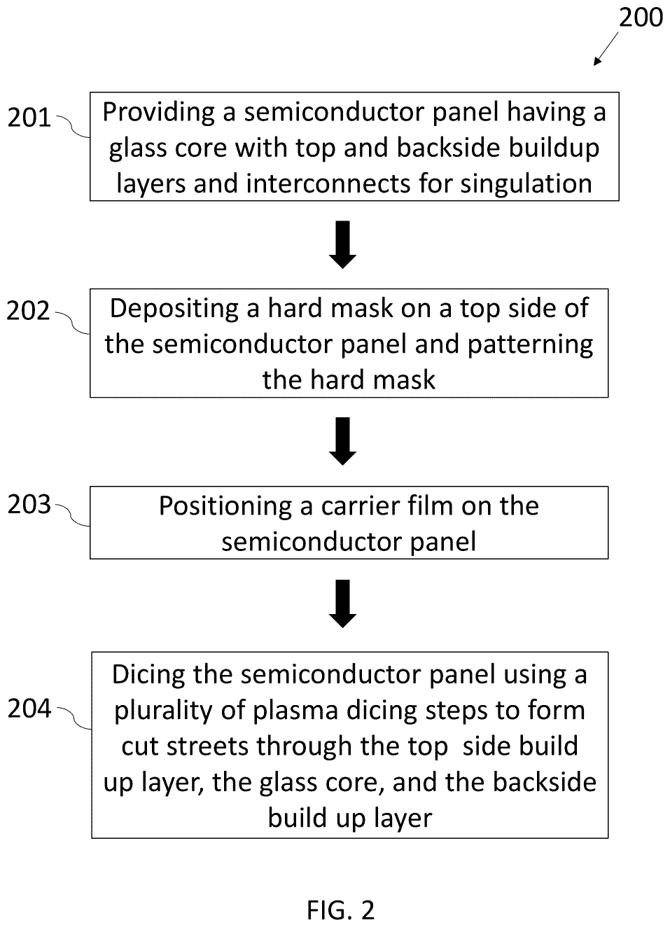

FIG. 2 shows a simplified flow diagram for an exemplary method 200 with operations 201 to 204 according to an aspect of the present disclosure.

The operation 201 may be directed to providing a semiconductor panel having a glass core with topside and backside build-up layers and interconnects for singulation/dicing.

The operation 202 may be directed to depositing a hard mask on a topside of the semiconductor panel and patterning the hard mask.

The operation 203 may be directed to positioning a carrier film on the semiconductor panel.

The operation 204 may be directed to dicing the semiconductor panel using a plurality of plasma dicing steps to form cut-streets through the topside build-up layer, the glass core, and the backside build-up layer.

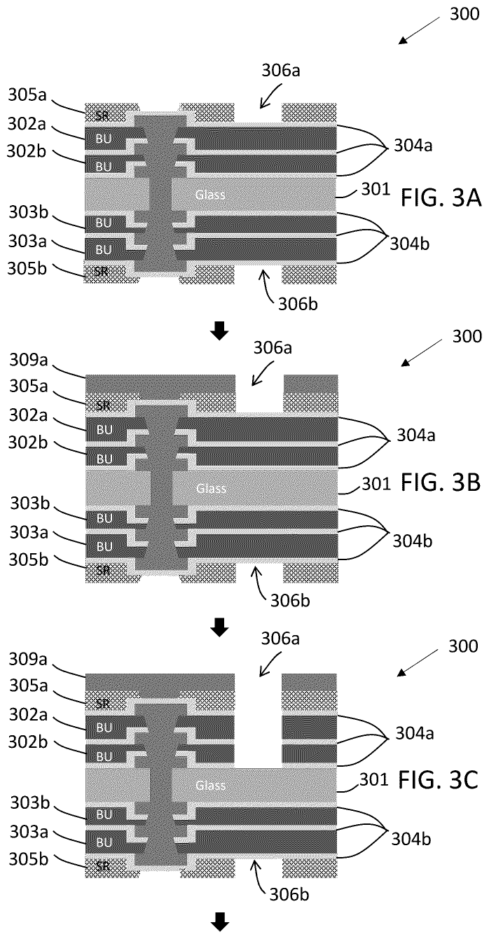

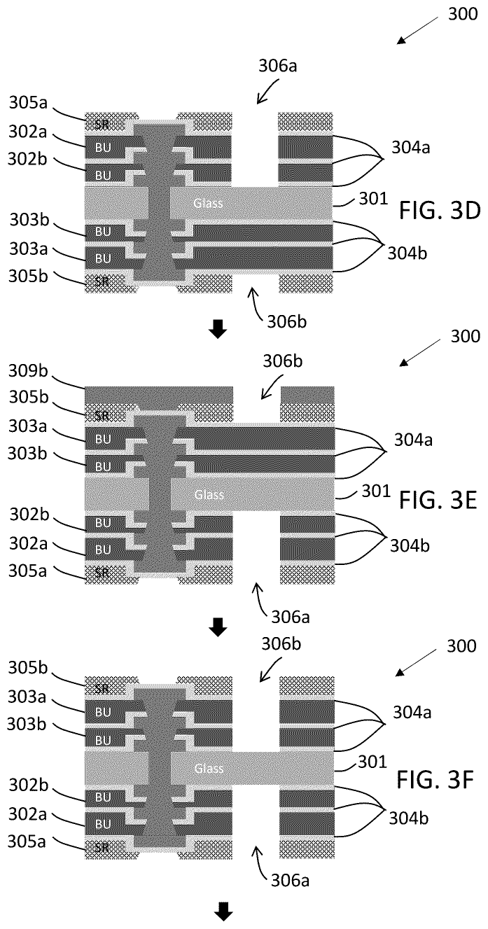

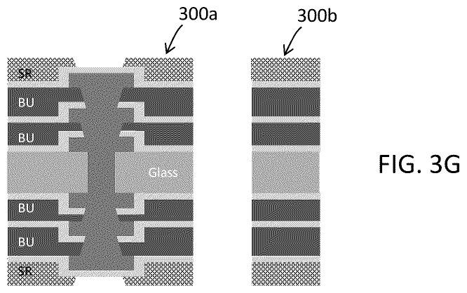

FIGS. 3A through 3G show exemplary representations of another method for dicing a semiconductor panel 300 according to an aspect of the present disclosure.

In FIG. 3A, the semiconductor panel 300 includes a glass core 301 having topside build-up layers 302a and 302b and backside build-up layers 303a and 303b. A topside solder resist layer 305a may be disposed over the topside build-up layers 302a and a backside solder resist layer 305b may be disposed over the backside build-up layers 303a. It should be understood that the number of build-up layers that may be used will vary depending on a semiconductor layout design.

In an aspect, a plurality of topside insulating layers 304a may be disposed between the topside solder resist layer 305a, the topside build-up layers 302a, the topside build-up layers 302b, and the glass core 301, and similarly, a plurality of backside insulating layers 304b may be disposed between the backside solder resist layer 305b, the backside build-up layers 303a, the backside build-up layers 303b and the glass core 301.

In an aspect, the topside solder resist layer 305a may have a topside opening 306a and the backside solder resist layer 305b may have a backside opening 306b, which are positioned at a location for a cut-street to be used for dicing/singulation of the semiconductor panel 300. It should be understood that the semiconductor panel 300 may have a plurality of cut-streets that will need to be formed for dicing/singulation.

In another aspect, as shown in FIG. 3A, an interconnect 307 may be formed in the semiconductor panel 300 to connect the topside build-up layers 302a and 302b with the backside build-up layers 303a and 303b, as well as providing connections with other semiconductor components (not shown). It should be understood that the interconnect 307 is representative of the various through glass vias (TGVs), microvias and other interconnects that may be used for a semiconductor layout design.

In FIG. 3B, the semiconductor panel 300 may be provided with a first hard mask layer 309a, e.g., a Cu mask layer, that may be deposited on the topside solder resist 305a and patterned by a conventional lithography method to maintain the opening 306a. The hard mask layer 309a may be provided as a protective layer that enables the cut-streets to be selectively formed in the semiconductor panel 300 during the dicing/singulation process.

In FIG. 3C, the depth of the topside opening 306a may be further increased by a first plasma dicing step to remove the topside build-up layers 302a and 302b, as well as removing the topside insulating layers 304a to expose the glass core 301 and form topside cut-streets as part of the dicing process. The first plasma dicing step may be performed using a conventional plasma etch technology; for example, a reactive ion etching method using a carbon tetrafluoride/oxygen plasma.

In FIG. 3D, the first hard mask layer 109a, e.g., a Cu mask layer, may be removed from the topside solder resist 105a using a conventional layer stripping method, e.g., a Cu etching method.

In FIG. 3E, the semiconductor panel 300 may be turned over and provided with a second hard mask layer 309b, e.g., a Cu mask layer, that may be deposited over the backside solder resist layer 305b and patterned by a conventional lithography method to maintain the opening 306a. The hard mask layer 309b may be provided as a protective layer that enables the cut-streets to be selectively formed in the semiconductor panel 300 during the dicing/singulation process.

In an aspect, the depth of the backside opening 306b may be further increased by a second plasma dicing step to remove the backside build-up layers 303b and 303a and the backside insulating layers 304b to expose the glass core 301 and form backside cut-streets as part of the dicing process. The second plasma dicing step may be performed using a conventional plasma etch technology; for example, a reactive ion etching method using a carbon tetrafluoride/oxygen plasma.

In FIG. 3F, the second hard mask, e.g., a Cu mask layer, may be removed from the backside solder resist layer 305b using a conventional layer stripping method, e.g., a Cu etching method.

In FIG. 3G, the dicing/singulation of the semiconductor panel 300 may be completed by a mechanical sawing step to remove the glass core 301 to form singulated dies 300a and 300b, which may be further processed by conventional procedures.

In an alternative step, a third plasma dicing step may be performed to remove the glass core 301 before the removal of the second hard mask 309b. The third plasma dicing step may be performed using a conventional plasma etch technology; for example, a reactive ion etching method using a nitrogen trifluoride/oxygen plasma. In an aspect, depending on the glass type used, an acid rinse cycle may be needed to remove impurities, e.g., salt byproducts.

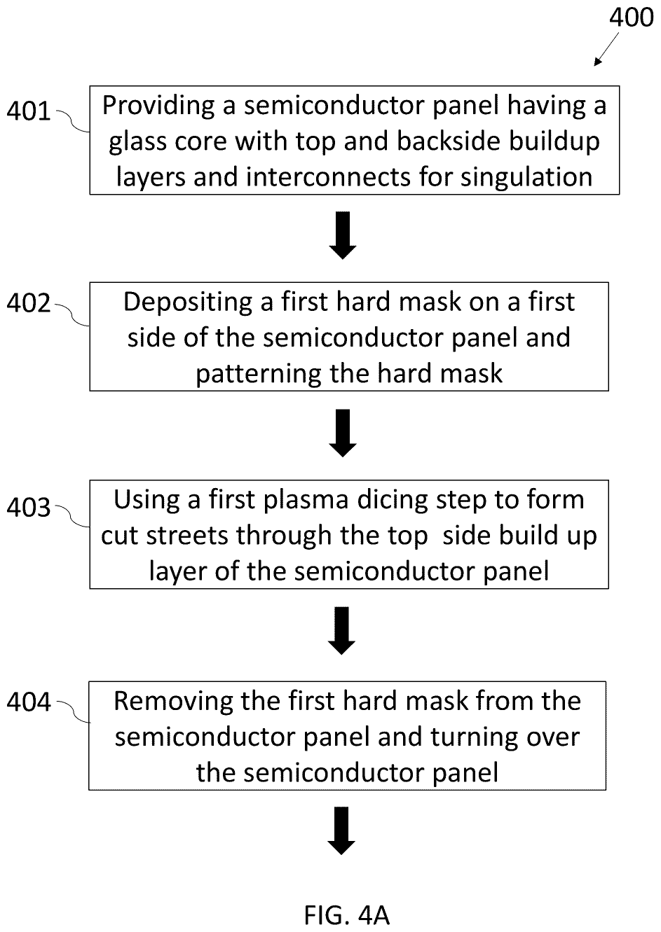

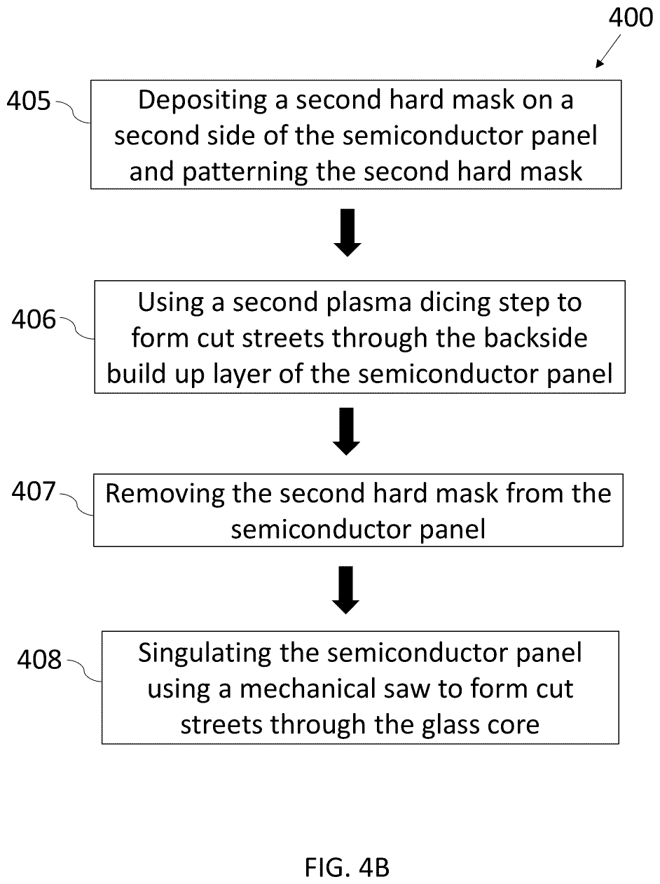

FIGS. 4A and 4B show a simplified flow diagram for another exemplary method 400 with operations 401 to 408 according to an aspect of the present disclosure.

The operation 401 may be directed to providing a semiconductor panel having a glass core with topside and backside build-up layers and interconnects for singulation/dicing.

The operation 404 may be directed to depositing a first hard mask on a first side of the semiconductor panel and patterning the hard mask.

The operation 403 may be directed to using a first plasma dicing step to form cut-streets through the topside build-up layer of the semiconductor panel.

The operation 404 may be directed to removing the first hard mask from the semiconductor panel and turning over the semiconductor panel.

The operation 405 may be directed to depositing a second hard mask on a second side of the semiconductor panel and patterning the second hard mask.

The operation 406 may be directed to using a second plasma dicing step to form cut-streets through the backside build-up layer of the semiconductor panel.

The operation 407 may be directed to removing the second hard mask from the semiconductor panel.

The operation 408 may be directed to dicing/singulating the semiconductor panel using a mechanical sawing step to form cut-streets through the glass core. The third dicing step may be a mechanical sawing step or a third plasma dicing step.

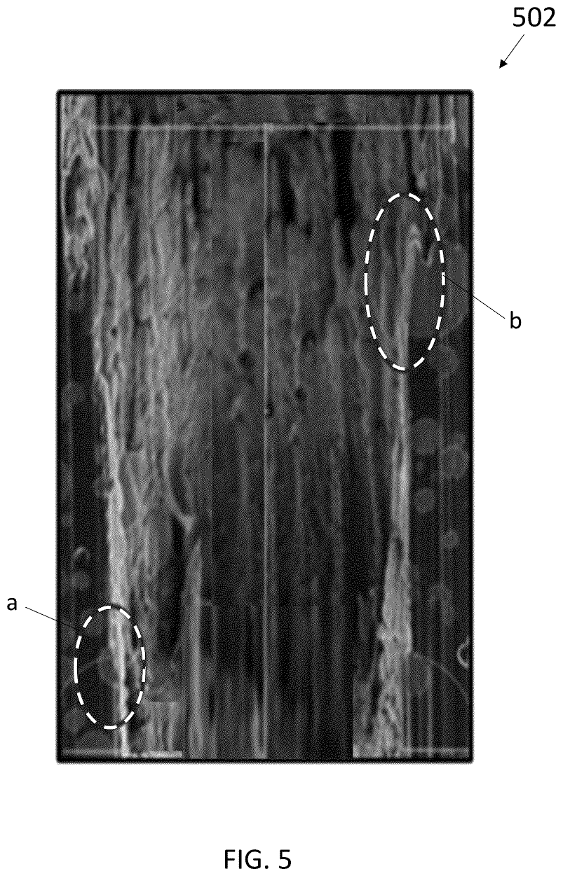

FIG. 5 shows an exemplary image of a sidewall of build-up layers 502 according to an aspect of the present disclosure. The build-up layers 502 at sections a and b have edge sidewalls with a morphology of semi-sphere fillers, which are indicative of reduced heat-induced stress in the build-up layers, as well as in the glass core, when forming cut-streets at a lower temperature.

It will be understood that any property described herein for a particular method for dicing and singulation using plasma etching/cutting for a semiconductor panel may also hold for any semiconductor wafer using the present methods described herein. It will also be understood that any property described herein for a specific method may hold for any of the methods described herein. Furthermore, it will be understood that for the methods described herein, not necessarily all the operations described will be shown in the accompanying drawings or method, but only some (not all) components or operations may be disclosed.

To more readily understand and put into practical effect the plasma cutting of semiconductor panels having present reduced stress sidewalls, they will now be described by way of examples. For the sake of brevity, duplicate descriptions of features and properties may be omitted.

### EXAMPLES

Example 1 provides a method that includes providing a semiconductor panel having a glass core with topside build-up (BU) layers on the glass core, backside BU layers on the glass core, and interconnects in the topside and backside BU layers, depositing a hard mask on the semiconductor panel and patterning the hard mask, and dicing the semiconductor panel using plasma dicing to cut through the topside BU layers and the backside BU layers to form cut-streets.

Example 2 may include the method of example 1 and/or any other example disclosed herein, for which the dicing of the semiconductor panel further includes using a plasma dicing to cut through the glass core.

Example 3 may include the method of example 2 and/or any other example disclosed herein, for which the dicing of the semiconductor panel further includes using an acid rinse to remove metal salts during the plasma dicing of the glass core.

Example 4 may include the method of example 1 and/or any other example disclosed herein, for which the plasma dicing further comprises plasma dicing through the topside BU layers, then plasma dicing through the glass core, and then plasma dicing through the backside BU layers.

Example 5 may include the method of example 4 and/or any other example disclosed herein, for which the plasma dicing comprises plasma dicing using reactive ion etching.

Example 6 may include the method of example 5 and/or any other example disclosed herein, for which the plasma dicing of the topside BU layers and the backside BU layers comprises using carbon tetrafluoride/oxygen plasma, and the plasma dicing of the glass core comprises using nitrogen trifluoride/oxygen plasma.

Example 7 may include the method of example 6 and/or any other example disclosed herein, for which the plasma dicing comprises plasma dicing at a temperature below 100° C.

Example 8 may include the method of example 1 and/or any other example disclosed herein, which further includes positioning the semiconductor panel on a carrier film.

Example 9 provides a product made by a process that includes providing a semiconductor panel including a glass core having a topside and a backside, with topside build-up (BU) layers and backside BU layers, and interconnects, depositing at a first hard mask on the semiconductor panel over the topside BU layers and patterning the first hard mask to form a first opening for a plurality of cut-streets, plasma dicing portion of the topside BU layers exposed in the first opening, depositing a second hard mask on the semiconductor panel over the backside BU layers and patterning the second hard mask to form a second opening for the plurality of cut-streets, and plasma dicing portion of the backside BU layers.

Example 10 may include the product of example 9 and/or any other example disclosed herein, for which the process further includes using mechanical dicing to cut through the glass core to dice the semiconductor panel.

Example 11 may include the product of example 9 and/or any other example disclosed herein, for which the process further includes using plasma dicing to cut through the glass core to dice the semiconductor panel.

Example 12 may include the product of example 11 and/or any other example disclosed herein, for which the plasma dicing comprises reactive ion etching.

Example 13 may include the product of example 12 and/or any other example disclosed herein, for which the plasma dicing of the topside and backside BU layers comprises using a carbon tetrafluoride/oxygen plasma, and the plasma dicing of the glass core comprises using a nitrogen trifluoride/oxygen plasma.

Example 14 may include the product of example 13 and/or any other example disclosed herein, for which the plasma dicing comprises plasma dicing at a temperature below 100° C.

Example 15 may include the product of example 11 and/or any other example disclosed herein, for which the process further includes using an acid rinse to remove metal salts when plasma dicing the glass core.

Example 16 may include the product of example 9 and/or any other example disclosed herein, for which the process further includes removing the first hard mask after the plasma dicing the topside BU layers.

Example 17 may include the product of example 16 and/or any other example disclosed herein, for which the process further includes repositioning the semiconductor panel by turning the semiconductor panel over to have the backside of the semiconductor panel facing up after removing the first hard mask.

Example 18 may include the product of example 17 and/or any other example disclosed herein, for which the process further includes removing the second hard mask after plasma dicing the backside BU layers.

Example 19 provides a device having a glass core having a first surface, a glass sidewall, and a second surface, and a first build-up (BU) layer having a first BU sidewall disposed on the first surface of the glass core and a second BU layer having a second BU sidewall disposed on the second surface of the glass core, for which the first BU sidewall and second BU sidewall have a morphology that includes semi-sphere fillers.

Example 20 may include the device of example 19 and/or any other example disclosed herein, for which the first BU sidewall and second BU sidewall are vertically aligned and co-planar with the glass sidewall.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A method comprising:
providing a semiconductor panel comprising a glass core with topside build-up (BU) layers on the glass core, backside BU layers on the glass core, and interconnects in the topside and backside BU layers;
depositing a hard mask on the semiconductor panel and patterning the hard mask; and
dicing the semiconductor panel using plasma dicing to cut through the topside BU layers and the backside BU layers.

2. The method of claim 1, wherein the dicing of the semiconductor panel further comprises using plasma dicing to cut through the glass core.

3. The method of claim 2, wherein the dicing of the semiconductor panel further comprises using an acid rinse to remove metal salts during plasma dicing of the glass core.

4. The method of claim 1, wherein the plasma dicing further comprises plasma dicing through the topside BU layers, then plasma dicing through the glass core, and plasma dicing through the backside BU layers.

5. The method of claim 4, wherein the plasma dicing comprises using reactive ion etching.

6. The method of claim 5, wherein the plasma dicing of the topside BU layers and backside BU layers comprises using a carbon tetrafluoride/oxygen plasma, and the plasma dicing of the glass core comprises using a nitrogen trifluoride/oxygen plasma.

7. The method of claim 6, wherein the plasma dicing comprises plasma dicing at a temperature below 100° C.

8. The method of claim 1, further comprises positioning the semiconductor panel on a carrier film.

9. A product made by a process comprising:
providing a semiconductor panel comprising a glass core having a topside and a backside, with topside build-up (BU) layers, backside BU layers, and interconnects;
depositing at a first hard mask on the semiconductor panel over the topside BU layers and patterning the first hard mask to form a first opening for a plurality of cut-streets;
plasma dicing portions of the topside BU layers exposed in the first opening;
depositing a second hard mask on the semiconductor panel over the backside BU layers and patterning the second hard mask to form a second opening for the plurality of cut-streets; and
plasma dicing portions of the backside BU layers exposed in the second opening.

10. The product of claim 9, wherein the process further comprises using mechanical dicing to cut through the glass core to dice the semiconductor panel.

11. The product of claim 9, wherein the process further comprises using plasma dicing to cut through the glass core to dice the semiconductor panel.

12. The product of claim 11, wherein the plasma dicing comprises using reactive ion etching.

13. The product of claim 12, wherein the plasma dicing of the topside BU layers and the backside BU layer comprises using a carbon tetrafluoride/oxygen plasma, and the plasma dicing of the glass core comprises using a nitrogen trifluoride/oxygen plasma.

14. The product of claim 13, wherein the plasma dicing comprises plasma dicing at a temperature below 100° C.

15. The product of claim 11, wherein the process further comprises using an acid rinse to remove metal salts when plasma dicing the glass core.

16. The product of claim 9, wherein the process further comprises removing the first hard mask after the plasma dicing of the topside BU layers.

17. The product of claim 16, wherein the process further comprises repositioning the semiconductor panel by turning the semiconductor panel over to have the backside of the semiconductor panel facing up after removing the first hard mask.

18. The product of claim 17, wherein the process further comprises removing the second hard mask after the plasma dicing of the backside BU layers.

19. A device comprising:
a glass core having a first surface, a glass sidewall, and a second surface; and
a first build-up (BU) layer having a first BU sidewall disposed on the first surface of the glass core and a second BU layer having a second BU sidewall disposed on the second surface of the glass core, wherein the first BU sidewall and second BU sidewall have a morphology comprising semi-sphere fillers.

20. The device of claim 19, wherein the first BU sidewall and second BU sidewall are vertically aligned and co-planar with the glass sidewall.
